(19) United States
(12) Patent Application Publication
(10) Pub. No.: US 2007/0007587 A1
(43) Pub. Date: Jan. 11, 2007

(54) Diode

(76) Inventors: Reiner Barthelmess, Soest (DE); Franz-Josef Niedernostheide, Muenster (DE); Hans-Joachim Schulze, Ottobrunn (DE)

Correspondence Address: BAKER BOTTS, L.L.P., 98 SAN JACINTO BLVD., SUITE 1500, AUSTIN, TX, 78701-4039, US

(21) Appl. No.: 11/428,741

(22) Filed: Jul. 5, 2006

(30) Foreign Application Priority Data
Jul. 5, 2005 (DE) 10 2005 031 398.1

(51) Int. Cl. H01L 29/94

(52) U.S. Cl. 257/330

(57) ABSTRACT

A diode has a semiconductor body (1), which has a front side (11) and a rear side (12) opposite the front side (11) in a vertical direction (z) of the semiconductor (1), and in which a heavily n-doped zone (5), a weakly n-doped zone (4), a weakly p-doped zone (3) and a heavily p-doped zone (2) are arranged successively in the vertical direction (z) proceeding from the rear side (12) toward the front side (11). In order to produce the weakly p-doped zone (3) of such a diode, aluminum may be introduced into the semiconductor body (1) proceeding from the front side (11). Optionally, the diode may have a field stop zone (9). Such a field stop zone (9) may be produced by rear-side indiffusion of sulfur and/or selenium into the semiconductor body (1).

### PRIORITY

This application claims priority from German Patent Application No. DE 10 2005 031 398.1, which was filed on Jul. 5, 2005, and is incorporated herein by reference in its entirety.

### TECHNICAL FIELD

The invention relates to a diode, in particular a power diode comprising a heavily p-doped layer, a weakly n-doped layer and also a heavily n-doped layer. Applications of such diodes are found primarily in power electronics, for example in high-voltage direct current transmission installations.

### BACKGROUND

It is known that in diodes of this type, a transient excessive voltage increase of the anode-cathode voltage generally occurs during switch-on with high rates of current rise.

The maximum transient excessive voltage increase that occurs when the diode is switched on is usually set by a suitable choice of the diode thickness or a suitable choice of the doping of the weakly n-doped zone. In this case, reducing the diode thickness or increasing the doping concentration of the weakly n-doped zone results in smaller overvoltages.

The disadvantage of this measure is that this is accompanied by a reduction of the reverse voltage of the diode. Furthermore, increasing the doping concentration of the weakly n-doped zone has a disadvantageous effect on the diode's resistance to cosmic radiation.

### SUMMARY

A diode comprising a heavily p-doped zone, a weakly n-doped zone and a heavily n-doped zone is provided in which the transient excessive voltage increase of the anode-cathode voltage that occurs when the diode is switched on with high rates of current rise is reduced without the reverse voltage of the diode being significantly reduced at the same time.

In one embodiment, a diode may comprise a semiconductor body having a front side and a rear side opposite the front side in a vertical direction of the semiconductor body, and in which a heavily n-doped zone, a weakly n-doped zone, a weakly p-doped zone and a heavily p-doped zone are arranged successively in the vertical direction proceeding from the rear side toward the front side.

### BRIEF DESCRIPTION OF THE DRAWINGS

The invention is explained in more detail below with reference to figures, in which:

FIG. 1 shows a cross section through a diode, in which diode a weakly p-doped zone is arranged between the heavily p-doped zone and the weakly n-doped zone,

FIG. 2 shows a diode corresponding to FIG. 1, in which an n-doped field stop zone is additionally arranged between the heavily n-doped zone and the weakly n-doped zone,

FIG. 3 shows the profile of the net dopant concentration in the vertical direction of a diode according to an embodiment in comparison with a conventional diode,

FIG. 4 shows the temporal profile of the diode voltage of a diode with the temporal profile of the diode voltage of a conventional diode, in each case during the switch-on operation and presupposing a constant current rise.

### DETAILED DESCRIPTION

The weakly p-doped zone, in the vertical direction, may have a thickness amounting to at least 25% and at most 50% of the thickness of the semiconductor body in the vertical direction. The weakly p-doped zone, in the vertical direction, may have a thickness amounting to at least 40% and at most 50% of the thickness of the semiconductor body in the vertical direction. The net acceptor dose in the weakly p-doped zone can be between 1·10¹² cm⁻² and 2·10¹² cm⁻². The net acceptor concentration in the weakly p-doped zone can be between 1·10¹² cm⁻³ and 1·10¹⁴ cm⁻³. The net acceptor concentration in the weakly p-doped zone can be from 1 to 10 times the net donor concentration of the n-doped zone. The diode may comprise a breakdown voltage at which the electric field strength at the junction between the weakly n-doped layer and the heavily n-doped layer is at least 5·10⁴ V/cm. The semiconductor body may have an edge bevel on its the heavily n-doped zone. The net dopant concentration of the weakly p-doped zone can be between 0.02 and 50 times the net dopant concentration of the weakly n-doped zone. The net dopant concentration of the weakly p-doped zone can be between 0.1 and 10 times the net dopant concentration of the weakly n-doped zone. The net dopant concentration of the weakly p-doped zone can be approximately constant in the vertical direction. The diode may comprise an n-doped field stop zone, the net dopant concentration of which is greater than the net dopant concentration of the weakly n-doped zone, the net dopant concentration of which is less than the net dopant concentration of the heavily n-doped zone and which is arranged between the heavily n-doped zone and the weakly n-doped zone.

In one embodiment, a method for producing such a diode may comprise the steps of providing the semiconductor body, which has a weak n-type basic doping, and producing the weakly p-doped zone by introducing aluminum into the semiconductor body proceeding from the front side.

Aluminum can be introduced by means of implantation. The aluminum, after being introduced into the semiconductor body, can be indiffused into the semiconductor body to a depth—measured from the front side—of between 25% and 50% of the total thickness d1. The aluminum, after being introduced into the semiconductor body, can also be indiffused into the semiconductor body to a depth—measured from the front side—of between 40% and 50% of the total thickness d1.

In one embodiment, a method for producing such a diode may comprise the steps providing the semiconductor body, which has a weak p-type basic doping, and producing an n-doped field stop zone by indiffusing sulfur and/or selenium into the semiconductor body proceeding from the rear side thereof.

The diode according to an embodiment has a semiconductor body, in which a heavily n-doped zone, a weakly n-doped zone, a weakly p-doped zone and a heavily p-doped zone are arranged successively in a vertical direction.

The diode according to an embodiment, thus, additionally has a weakly p-doped zone between the heavily p-doped zone and the weakly n-doped zone.

In accordance with one embodiment, the thickness of the weakly p-doped zone amounts to at least 25% and at most 50% of the thickness of the semiconductor body.

Within the meaning of the present application, the term “thickness” is always to be understood as its dimension in the vertical direction.

The net acceptor dose, that is to say the integral of the net dopant concentration, in the weakly p-doped zone is preferably between 1·10¹² cm⁻² and 2·10¹² cm⁻².

The electric field strength which occurs at the junction between the weakly n-doped layer and the heavily n-doped layer in the presence of breakdown voltage is preferably between 2·10⁴ V/cm and 1·10⁵ V/cm, particularly preferably 5·10⁴ V/cm.

In order that the electric field of the space charge zone that forms between the weakly p-doped layer and the weakly n-doped layer in the off state of the diode is reduced uniformly in the edge region of the diode, the semiconductor body may have an edge bevel extending in a manner proceeding from the front to beyond the pn junction formed between the weakly p-doped zone and the weakly n-doped zone.

The net dopant concentration of the weakly p-doped zone is preferably chosen to be approximately constant in the vertical direction, or falls from the surface into the depth with a smallest possible gradient.

In order to further reduce the transient excessive voltage increase that occurs when the diode is switched on and to achieve a soft turn-off of the diode, the latter may also be provided with a deep n-doped field stop zone arranged between the heavily n-doped zone and the weakly p-doped zone.

In the figures, identical reference symbols show identical parts with the same meaning.

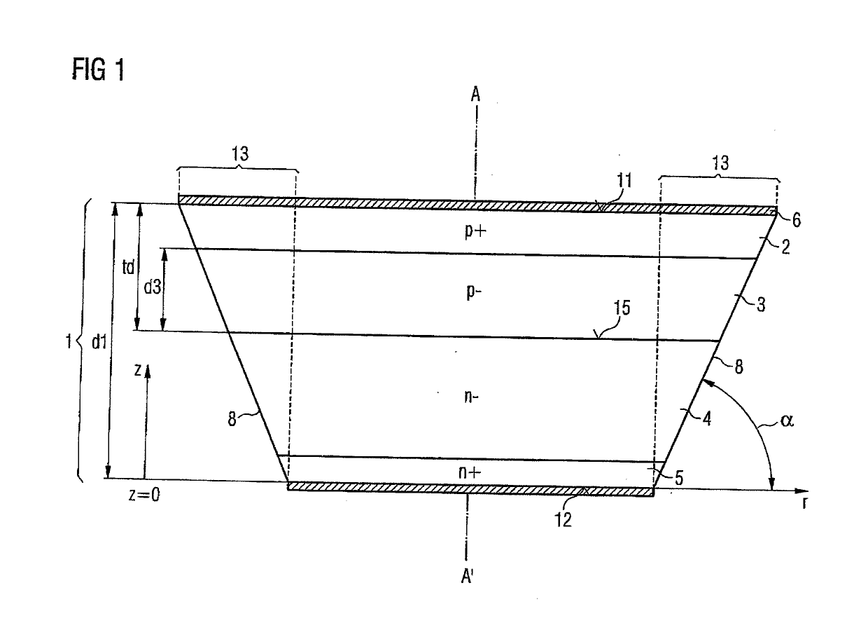

FIG. 1 shows a cross section through a diode comprising a semiconductor body 1, in which a heavily n-doped zone 5, a weakly n-doped zone 4, a weakly p-doped zone 3 and a heavily p-doped zone 2 are arranged successively in a vertical direction z.

The semiconductor body 1 has an anode metallization 6 on its front side 11 and a cathode metallization 7 on its rear side 12 opposite the front side 11.

Furthermore, the semiconductor body 1 has an optional edge bevel in its edge region 13 in a lateral direction r perpendicular to the vertical direction z, said edge bevel extending in a manner proceeding from the front side 11 to beyond the pn junction 15 formed between the weakly p-doped zone 3 and the weakly n-doped zone 4 as far as the rear side 12. The edge bevel is formed by virtue of a lateral edge 8 of the semiconductor body 1 forming an angle α of preferably 30° to 50° with the rear side 12 of said semiconductor body.

As an alternative or in addition to the edge bevel 8, the semiconductor body 1 may also have a planar edge termination, for example one or a plurality of field rings, preferably with in each case a field plate that is arranged on the front side 11 and makes contact with the relevant field ring, in the edge region 8 of said semiconductor body.

The semiconductor body 1 has a thickness d1 in the vertical direction z. The thickness d3 of the weakly p-doped zone 3 in the vertical direction z preferably amounts to at least 25% and at most 50% of the thickness d1 of the semiconductor body 1.

The net acceptor concentration of the weakly p-doped zone 3 is preferably between 1·10¹² cm⁻³ and 1·10¹⁴ cm⁻³, particularly preferably between 5·10¹² cm⁻³ and 5·10¹³ cm⁻³.

The net acceptor dose of the weakly p-doped zone 3 is preferably between 1·10¹² cm⁻² and 2·10¹² cm⁻².

The thickness d1 of the semiconductor body 1 in the vertical direction z is preferably dimensioned such that, at the breakdown voltage of the diode, a field strength of at least 5·10⁴ V/cm is established at the junction between the weakly n-doped zone 4 and the heavily n-doped zone 5. This means that the diode is dimensioned with regard to a so-called punch-through of the space charge zone through the weakly n-doped zone 4.

In order to achieve a uniform reduction of the electrical field in the semiconductor body 1 in the off state of the diode in the edge region 13 and the region near the edge, said semiconductor body may have an edge termination, for example an edge bevel 8. In this case, the edge bevel 8 preferably extends in a manner proceeding from the front side 11 of the semiconductor body 1 beyond the pn junction 15 between the weakly p-doped zone 3 and the weakly n-doped zone 4.

Instead of or in addition to an edge bevel 8, it is also possible to provide other edge terminations, for example field rings with or without field plates on the front side 11 of the semiconductor body 1.

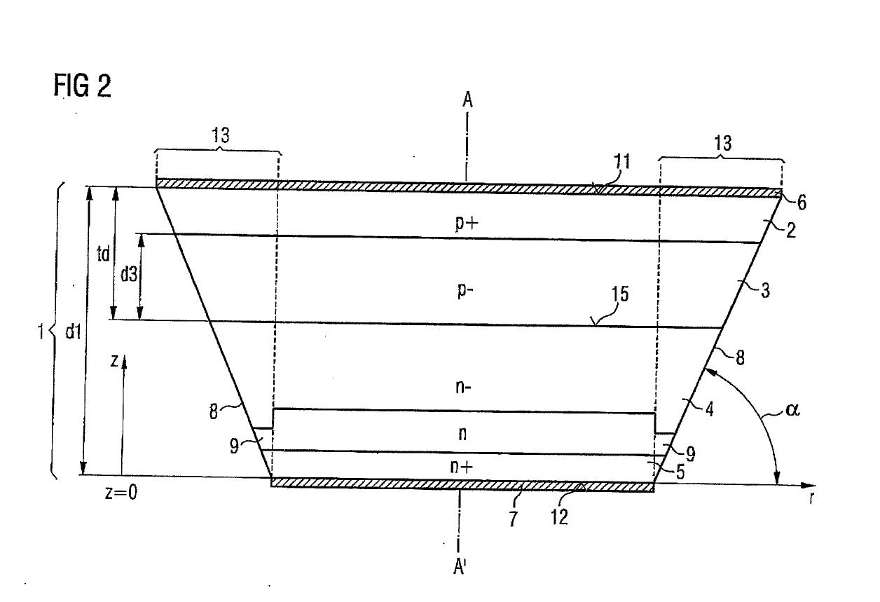

As is illustrated in FIG. 2, the diode according to an embodiment may optionally have an n-doped field stop zone 9 arranged between the weakly p-doped zone 3 and the heavily n-doped zone 5. The field stop zone 9 may be directly adjacent to the heavily n-doped zone 5 in a lateral direction—as illustrated in FIG. 2—or be spaced apart from said zone in the vertical direction z—in a manner not illustrated. In the last-mentioned case, a portion of the weakly n-doped zone 4 is then situated between the field stop zone 9 and the heavily n-doped zone 5.

The field stop zone 9 shown in FIG. 2 is formed simply in a contiguous manner. As an alternative to this, however, the field stop zone 9 may also be formed from two or more partial zones that are spaced apart from one another in a lateral direction r and/or vertical direction z.

In accordance with one preferred embodiment of such a diode, that side of the field stop zone 9 which faces the front side 11 is spaced apart from the front side 11 further in the edge region 13 of the semiconductor body 1 than in the central region of the semiconductor body 1.

The weakly p-doped zone 3 has, in the vertical direction z, a net dopant concentration ND that is preferably approximately constant or has a smallest possible gradient in the vertical direction z, the net acceptor doping concentration preferably falling monotonically with increasing distance from the surface.

The net dopant concentration ND in the region of the field stop zone 9 is preferably chosen to be greater than the net dopant concentration ND in the region of the weakly n-doped zone 4, but less than the net dopant concentration ND in the region of the heavily n-doped zone 5.

Besides the advantage of a reduced excessive voltage increase in the event of switch-on in comparison with a conventional diode, the additional weakly p-doped zone 3 also may have an advantageous effect on the edge termination of the diode if the latter is provided with a beveled edge 8 for a better edge blocking capability.

A further advantage of the additional weakly p-doped zone 3 is afforded when the diode is turned off with high rates of current rise from the conducting state to the off state. The holes that then flow away to the heavily p-doped zone 2 from the charge carrier plasma at least partly compensate for the negative acceptor charges in the space charge zone of the heavily p-doped zone 2 and thus provide for a reduction of the electric field strength and, accompanying this, a reduction of the charge carrier generation rate by impact ionization processes. For dynamic avalanche there may even be a positive effect if the net acceptor dose of the weakly p-doped zone 3, in the vertical direction z, is greater than approximately 1.3·10¹² cm⁻². This holds true particularly when the net dopant concentration N_{D} and the doping gradient in the vertical direction z of the semiconductor body 1 are set in such a way as to establish a relatively small gradient of the electric field strength in the vertical direction z upon transition to the off state in the weakly p-doped zone 3.

The weakly p-doped zone 3 may be produced for example by introducing aluminum proceeding from a semiconductor body 1 having a weakly n-conducting basic doping N_{D}, proceeding from the front side 11. For this purpose, the front side 11 may firstly be coated with aluminum and the latter may subsequently be indiffused, in a drive-in step, into the semiconductor body 1 as far as a depth td (see FIGS. 1 and 2) of between 25% and 50% of the total thickness D1, preferably between 40% and 50% of the total thickness d1.

An alternative method provides for introducing aluminum into the semiconductor body 1 by means of an ion implantation, preferably proceeding from the front side 11, and for subsequently providing a drive-in step.

The n-doped field stop zone 9 is preferably produced by means of a rear side indiffusion of sulfur and/or selenium.

As an alternative, the weakly p-doped zone 3 may also have a net dopant concentration ND that is constant or approximately constant in the vertical direction z. In this case, a semiconductor body 1 having a p-type basic doping may also be used for producing the diode. In said semiconductor body, proceeding from the rear side 12 of the semiconductor body 1, a deeply situated n-doping profile is produced with a low net doping concentration ND and a small gradient of the net dopant concentration ND in the vertical direction z by indiffusion of sulfur and/or selenium and/or hydrogen. The indiffusion of hydrogen is preferably effected from a plasma or a combination of proton irradiation followed by a thermal step in which the semiconductor body 1 is heated to temperatures of between 350° C. and 550° C., resulting in the formation of hydrogen-correlated donors.

Proton irradiation makes it possible, in particular, for the diode to exhibit a soft turn-off.

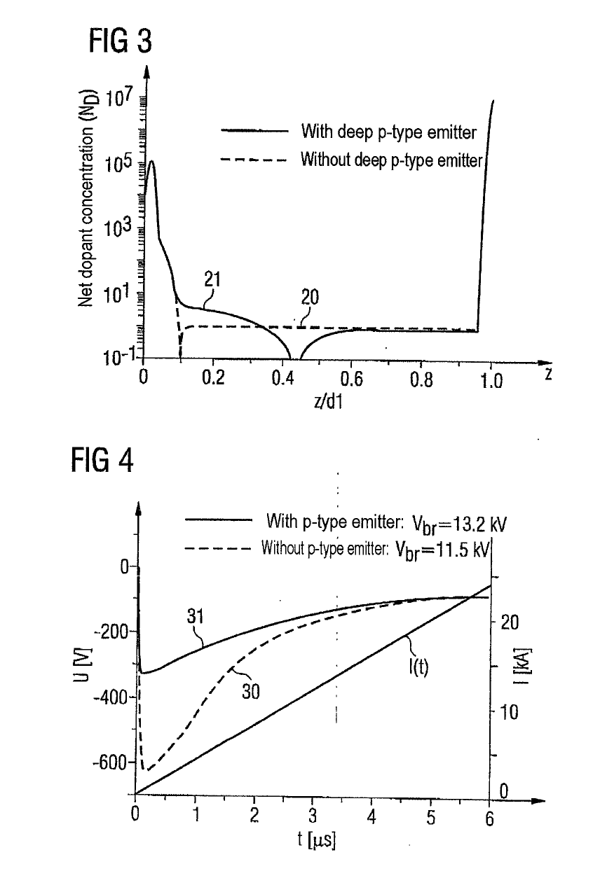

The diode in accordance with FIGS. 2 and 3 is preferably rotationally symmetrical about an axis A-A′ of symmetry, that is to say that it has a circular cross section in any sectional plane perpendicular to the vertical direction z.

As an alterative to this, the axis A-A′ of symmetry may also constitute a fourfold axis of symmetry, that is to say that the cross section of the diode in any sectional plane perpendicular to the vertical direction z is square.

The profile of the net dopant concentration 20 of a conventional diode and the profile of the net dopant concentration 21 of a diode with an additional weakly p-doped zone 8 are compared with one another in FIG. 3. Both diodes have the same thickness d1 in the vertical direction z.

The temporal profile 30 of the diode voltage U of a conventional diode and the temporal profile 31 of the diode voltage U of a diode according to an embodiment with a weakly p-doped zone 8 in accordance with FIG. 1 are compared with one another in FIG. 4. The diodes have the corresponding doping profiles shown in FIG. 3. For both diodes, the rise with respect to time in the diode current I(t) was chosen to be constant and identical in magnitude.

It can be discerned that in the case of a conventional diode, a negative voltage peak occurs which has a magnitude greater than 600 V, while the magnitude of the corresponding negative voltage peak of a diode according to an embodiment with a weakly p-doped zone amounts to only somewhat more than 300 V.

A further advantage can be that the additional weakly p-doped zone 8 can also bring about an increase in the breakdown voltage of the diode besides reducing the transient excessive voltage increase in the anode-cathode voltage that occurs when the diode is switched on.

Thus, by way of example, a diode with a net dopant concentration 21 in accordance with FIG. 3 has a breakdown voltage of 13.2 kV, while the breakdown voltage of the conventional diode with a net dopant concentration 20 in accordance with FIG. 3 is only 11.5 kV.

### LIST OF REFERENCE SYMBOLS

1 Semiconductor body
2 Heavily p-doped zone
3 Weakly p-doped zone
4 Weakly n-doped zone
5 Heavily n-doped zone
6 Metallization (anode)
7 Metallization (cathode)
8 Edge
9 Field stop zone
11 Front side
12 Rear side
13 Edge region
15 pn junction
20 Net dopant concentration (conventional diode)
21 Net dopant concentration (diode according to an embodiment)
30 Profile of the switch-on voltage (conventional diode)
31 Profile of the switch-on voltage (diode according to an embodiment)
d1 Thickness of the semiconductor body
d3 Thickness of the weakly p-doped zone
td Penetration depth of the weakly p-doped zone
t Time
z Vertical direction
r Lateral direction
A-A′ Axis
I Diode current
N_{D} Net dopant concentration
U Diode voltage

What is claimed is:

1. A diode comprising a semiconductor body having a front side and a rear side opposite the front side in a vertical direction of the semiconductor body, and in which a heavily n-doped zone, a weakly n-doped zone, a weakly p-doped zone and a heavily p-doped zone are arranged successively in the vertical direction proceeding from the rear side toward the front side.

2. A diode according to claim 1, wherein the weakly p-doped zone, in the vertical direction, has a thickness amounting to at least 25% and at most 50% of the thickness of the semiconductor body in the vertical direction.

3. A diode according to claim 1, wherein the weakly p-doped zone, in the vertical direction, has a thickness amounting to at least 40% and at most 50% of the thickness of the semiconductor body in the vertical direction.

4. A diode according to claim 1, wherein the net acceptor dose in the weakly p-doped zone is between 1·10¹² cm⁻² and 2·10¹² cm⁻².

5. A diode according to claim 1, wherein the net acceptor concentration in the weakly p-doped zone is between 1·10 cm¹² and 1·10¹⁴ cm⁻³.

6. A diode according to claim 1, wherein the net acceptor concentration in the weakly p-doped zone is from 1 to 10 times the net donor concentration of the n-doped zone.

7. A diode according to claim 1, comprising a breakdown voltage at which the electric field strength at the junction between the weakly n-doped layer and the heavily n-doped layer is at least 5·10⁴ V/cm.

8. A diode according to claim 1, wherein the semiconductor body has an edge bevel on its the heavily n-doped zone.

9. A diode according to claim 1, wherein the net dopant concentration of the weakly p-doped zone is between 0.02 and 50 times the net dopant concentration of the weakly n-doped zone.

10. A diode according to claim 9, wherein the net dopant concentration of the weakly p-doped zone is between 0.1 and 10 times the net dopant concentration of the weakly n-doped zone.

11. A diode according to claim 1, wherein the net dopant concentration of the weakly p-doped zone is approximately constant in the vertical direction.

12. A diode according to claim 1, comprising an n-doped field stop zone, the net dopant concentration of which is greater than the net dopant concentration of the weakly n-doped zone, the net dopant concentration of which is less than the net dopant concentration of the heavily n-doped zone and which is arranged between the heavily n-doped zone and the weakly n-doped zone.

13. A method for producing a diode comprising a semiconductor body having a front side and a rear side opposite the front side in a vertical direction of the semiconductor body, and in which a heavily n-doped zone, a weakly n-doped zone, a weakly p-doped zone and a heavily p-doped zone are arranged successively in the vertical direction proceeding from the rear side toward the front side, the method comprising the steps of:
providing the semiconductor body, which has a weak n-type basic doping, and
producing the weakly p-doped zone by introducing aluminum into the semiconductor body proceeding from the front side.

14. A method according to claim 13, wherein aluminum is introduced by means of implantation.

15. A method according to claim 13, wherein the aluminum, after being introduced into the semiconductor body, is indiffused into the semiconductor body to a depth—measured from the front side—of between 25% and 50% of the total thickness d1.

16. A method according to claim 15, wherein the aluminum, after being introduced into the semiconductor body, is indiffused into the semiconductor body to a depth—measured from the front side—of between 40% and 50% of the total thickness d1.

17. A method for producing a diode comprising a semiconductor body having a front side and a rear side opposite the front side in a vertical direction of the semiconductor body, and in which a heavily n-doped zone, a weakly n-doped zone, a weakly p-doped zone and a heavily p-doped zone are arranged successively in the vertical direction proceeding from the rear side toward the front side, comprising the steps:
providing the semiconductor body, which has a weak p-type basic doping, and
producing an n-doped field stop zone by indiffusing sulfur and/or selenium into the semiconductor body proceeding from the rear side thereof.

18. A method according to claim 17, wherein the weakly p-doped zone, in the vertical direction, has a thickness amounting to at least 25% and at most 50% of the thickness of the semiconductor body in the vertical direction.

19. A method according to claim 17, wherein the weakly p-doped zone, in the vertical direction, has a thickness amounting to at least 40% and at most 50% of the thickness of the semiconductor body in the vertical direction.

20. A method according to claim 17, wherein the net acceptor dose in the weakly p-doped zone is between 1·10¹² cm⁻² and 2·10¹² cm⁻².
